(19) United States
(12) Patent Application Publication
(10) Pub. No.: US 2005/0230354 A1
(43) Pub. Date: Oct. 20, 2005

(54) Method and composition of post-CMP wetting of thin films

(76) Inventor: Vishwas V. Hardikar, Phoenix, AZ (US)

Correspondence Address: INGRASSIA FISHER & LORENZ, P.C., 7150 E. CAMELBACK, STE. 325, SCOTTSDALE, AZ, 85251, US

(21) Appl. No.: 10/825,394

(22) Filed: Apr. 14, 2004

(51) Int. Cl. B24B 1/00; C09K 13/00; B44C 1/22; H01L 21/302

(52) U.S. Cl. 216/88; 252/79.1; 252/79.4; 438/692

(57) ABSTRACT

A method and composition for post-CMP wetting of a wafer having a dielectric thin film is provided. The composition is applied to a wafer after it has been exposed to a CMP slurry.

### TECHNICAL FIELD

This invention relates generally to post-CMP (“chemical mechanical polishing” or “chemical mechanical planarization”) cleaning, and more particularly, to wetting a wafer having a metal, inorganic, or organic dielectric thin film and that has been exposed to CMP.

### BACKGROUND OF THE INVENTION

As the size of microelectronic devices migrates towards submicron levels, the quality of semiconductor wafers and layers deposited thereon becomes increasingly important. Specifically, the requisite degree of planarity of the wafer surface increases due to the need for accuracy in these small devices. Planarization is desirable because the face of the wafer on which integrated circuitry is to be constructed is preferably substantially flat to facilitate the construction of reliable semiconductor junctions with subsequent layers of material that may be applied to the wafer. Composite thin film layers of conducting, insulating, and semiconducting materials preferably are also of a uniform thickness so as to be joined successfully to the semiconductor wafers or to other composite thin film layers. If a wafer surface is non-planar, subsequent photolithographic processing may result in poor optical resolution which in turn may hinder high-density features from being adequately printed. Additionally, if a conductor material step height is too large, open circuits may be created.

To produce the desired planarity on a wafer, a chemical mechanical polishing or chemical mechanical planarization (“CMP”) process can be applied to the wafer. CMP involves the polishing or removal of projections or imperfections that may be present on a semiconductor wafer or workpiece to create a uniform thickness and desired smoothness across the surface of the wafer. The wafer is generally contacted with a pad and an abrasive slurry for the removal of materials from the wafer at a selected rate. The CMP process can be used in several instances during the manufacture of an integrated circuit, for example, at the beginning of the manufacturing process, or after a metallization process.

After the wafer is exposed to CMP processing, particulates from the CMP slurry or from the wafers may undesirably adhere to the wafer surface as clumps of particles. These particle clumps may decrease the planarity of the wafer surface by collecting on the surface or resulting in unwanted trenches when subsequent layers are deposited and thus, are preferably removed. Moreover, particles that remain on the wafer may change the electrical characteristics of the area of the wafer surrounding the particles. Therefore, the wafers are typically subjected to cleaning before further processing.

Conventionally, just after CMP and at least once prior to and/or during the cleaning process, the wafer is kept wetted or rinsed with deionized water. However, it has been found that, in the case of wafers with metal, inorganic, or organic dielectriclayers deposited thereon, the usage of deionized water may deflocculate the particle clumps present on the wafer surface and may spread the particle clumps out across the wafer surface. As a result, more particles may adhere to the wafer to thereby increase the number of wafer defects. Moreover, it has been found that the usage of deionized water may cause poor wetting and streak marks on the surface of these types of wafers.

Accordingly, it is desirable to provide improved methods and compositions for rinsing and/or spraying a wafer having a metal, inorganic, or organic dielectricthin film material thereon that has been subjected to a CMP slurry so as to decrease the number of defects on the wafer. It is also desirable to provide a fluid that can be applied to the wafer that improves wetting and leaves minimal or no streak marks. Furthermore, other desirable features and characteristics of the present invention will become apparent from the subsequent detailed description of the invention and the appended claims, taken in conjunction with the accompanying drawings and this background of the invention.

### BRIEF DESCRIPTION OF THE DRAWINGS

The present invention will hereinafter be described in conjunction with the following drawing figures, wherein like numerals denote like elements, and

FIG. 1 is a top cutaway view of an exemplary CMP apparatus within which an embodiment of the CMP wetting composition of the present invention may be used;

FIG. 2 is a top view of another exemplary CMP apparatus in which an embodiment of the CMP wetting composition of the present invention may be used; and

FIG. 3 is a graph showing a comparison of the effectiveness of the exemplary CMP wetting composition to deionized water.

### DETAILED DESCRIPTION OF EXEMPLARY EMBODIMENTS

The following detailed description of the invention is merely exemplary in nature and is not intended to limit the invention or the application and uses of the invention. Furthermore, there is no intention to be bound by any theory presented in the preceding background of the invention or the following detailed description of the invention.

The drawing figures are intended to illustrate the general manner of employing the inventive method and composition in an apparatus and are not necessarily to scale. In the description and in the claims, the terms such as up, down, downward, inward, upper, lower, top, bottom, and the like may be used for descriptive purposes. However, it is understood that the embodiments of the invention described herein are capable of operation in other orientations than as shown, and the terms so used are only for the purpose of describing relative positions and are interchangeable under appropriate circumstances. The term “chemical mechanical planarization” is also often referred to in the industry as “chemical mechanical polishing,” and it is intended to encompass herein both terms by the use of “chemical mechanical planarization” and to represent each by the acronym “CMP.” For purposes of illustration only, the invention will be described as it applies to a CMP apparatus and to a CMP process and specifically as it applies to the CMP processing of a semiconductor wafer. It is not intended, however, that the invention be limited to these illustrative embodiments; instead, the invention is applicable to a variety of processing apparatus and to the processing and handling of many types of work pieces.

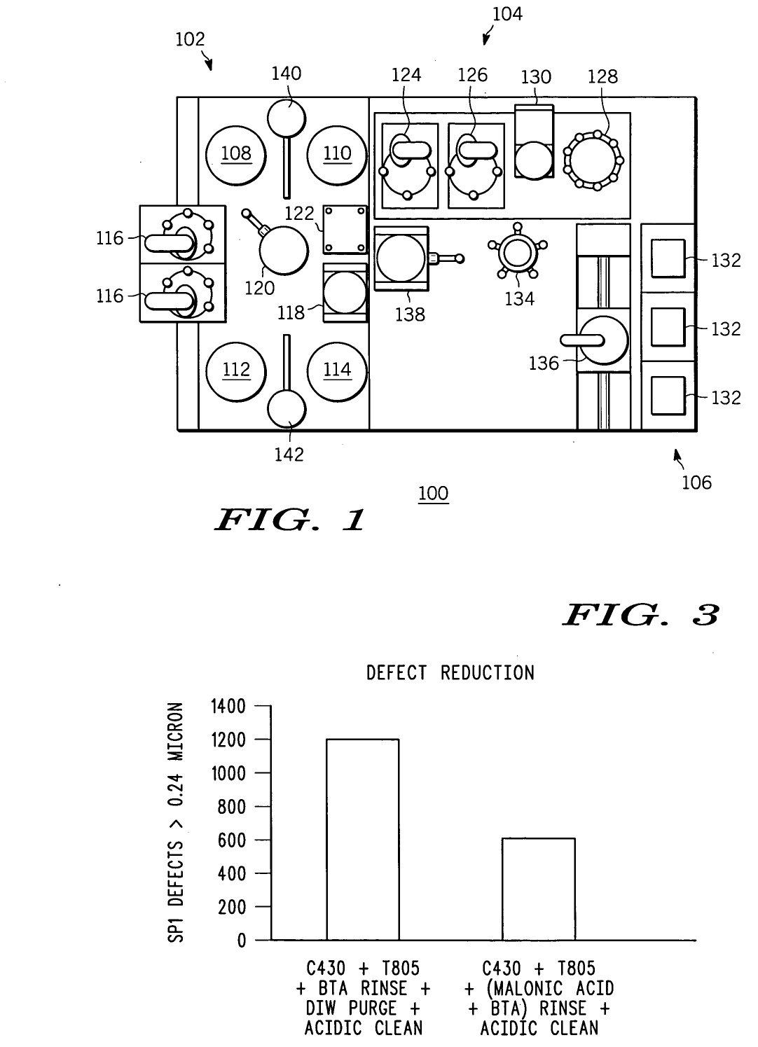

In accordance with an exemplary embodiment of the present invention, a method and composition for use on a wafer having a metal, inorganic, or organic dielectric layer thereon can be used after the chemical mechanical planarization of the workpiece. The method can be used to clean wafers having either a metal, inorganic, or organic dielectric layer that has been exposed to a CMP slurry. Thus, the method can include the step of polishing the layer via a CMP slurry and then wetting, rinsing or spraying the wafer before the cleaning process. These steps can be accomplished in a CMP apparatus such as a Momentum CMP apparatus available from Novellus Systems Inc., CMP division, of Chandler, Ariz. A representative CMP apparatus 100 with which these steps can be carried out and within which the CMP wetting composition of the present invention may be utilized is schematically illustrated in FIG. 1. This apparatus is merely exemplary of a CMP apparatus that can be employed in carrying out a CMP and cleaning process in accordance with various embodiments of the invention and it will be appreciated that any other suitable CMP apparatus may be used.

The apparatus 100 depicted is suitable for polishing or planarizing material from the surface of a wafer and can be configured to distribute the CMP wetting composition of the present invention to the wafer. As used herein, “wafer” shall mean semiconductor substrates, which may include layers of insulating, semiconducting, and conducting layers or features formed thereon and used to manufacture microelectronic devices. The apparatus 100 includes a multi-station polishing system 102, a clean system 104, and a wafer load/unload station 106. Additionally, the apparatus 100 preferably includes a cover (not shown) that isolates the apparatus 100 from the surrounding outside environment.

The exemplary polishing system 102 includes a load/unload station 106, four polishing stations, 108, 110, 112, and 114, a buff station 116, a stage 118, a robot 120, and optionally, a metrology station 122. The polishing stations 108 are configured to operate independently from one another and may be configured to perform specific functions, such as the delivery of CMP slurry to a wafer, or delivery of the CMP wetting composition of the present invention to a wafer. To this end, a slurry container (not shown) and CMP wetting composition container (not shown) may each be externally or internally associated with the polishing system 102 to supply the CMP slurry and/or CMP wetting composition to the polishing stations 108-114 through at least one supply channel (not shown). The delivery of CMP slurry can be supplied to a wafer via any one of numerous known methods. For example, the slurry can be supplied to a polishing platen for a through-the-pad polishing system, or to a wafer holder for systems in which the slurry is sprayed on to the wafer surface. Similarly, the CMP wetting composition of the present invention can be delivered through either a channel that is in communication with the same supply channel as the CMP slurry, or, alternatively, can be delivered through a separate supply channel. The CMP wetting composition of the present invention can also be supplied to the polishing platen for a through-the-pad polishing system so that the fluid can be applied to the wafer surface.

The clean system 104 is generally configured to remove unwanted particles or material from the wafer after it has been exposed to the CMP slurry. In this embodiment, the system 104 includes two clean stations 124, 126, a spin rinse dryer 128, and a robot 130 configured to transport the wafer between the clean stations 124, 126 and the spin rinse dryer 128. The clean system 104 can be either connected to or separate from the remainder of the CMP apparatus 100. If the clean system 104 is separate from the CMP apparatus 100, the wafers preferably may remain in a wet environment comprising the CMP composition of the present invention until they are ready to be transferred to one of the clean stations 124, 126.

During operation, at least one wafer is loaded into the apparatus 100 at the load/unload station 106. The wafers are typically transported into the apparatus 100 via a cassette 132. When the cassette 132 is suitably coupled to the apparatus, a dry robot 136 transports it to an intermediate staging area 134. From the staging area 134, the wafer can either be transported by the wet robot 138 to the metrology station 122 to undergo film characterization or can be transported to the stage 118 within the polishing system 102. The stage 118 is preferably configured to contain the CMP wetting composition of the present invention so that the wafer may be maintained in a wet environment, if placed therein. If the wafer is placed on the stage 118, the robot 120 picks up the wafer from the stage 118, and loads it onto one of the designated carriers on one of the polishing stations 108-114. At the end of polishing, the robot 120 transfers the wafer to the stage 118. The wet transport robot 138 then transfers the wafer to the clean system 104. The wafer is then cleaned and transported to the spin rinse dryer 130 to rinse and dry prior to transport to the load/unload station 106.

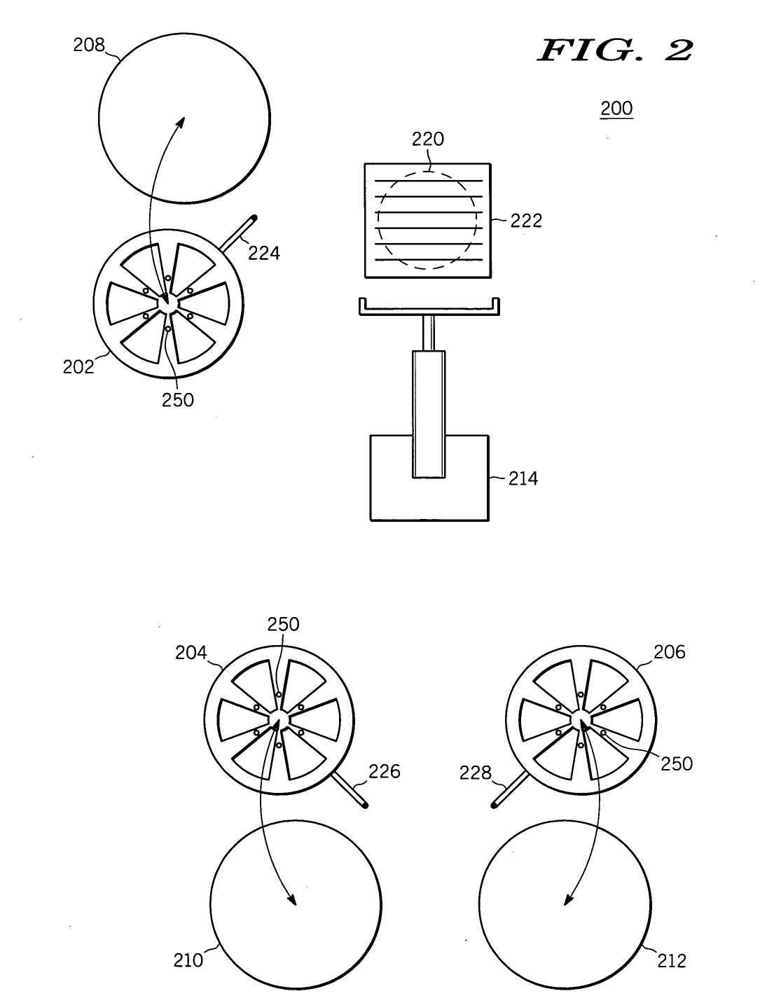

In yet another embodiment, the CMP wetting composition of the present invention can be used in a CMP apparatus 200, a top view of which is illustrated schematically in FIG. 2. Apparatus 200 may comprise a plurality of load cups 202, 204, 206. The CMP apparatus 200 is further detailed and described in U.S. application Ser. No. ______, which is incorporated herein by reference. Generally, the CMP apparatus 200 also includes a plurality of chemical mechanical planarization carrier heads 208, 210, 212 positioned about a centrally located robot 214. The robot 214 is configured to receive a wafer 220 (shown in phantom) and transport it, for example, from a cache 222 to one of the load cups 202-206. Each of the CMP carrier heads 208-212 is positioned over a polishing pad (not illustrated) that is configured to utilize a CMP slurry to polish the wafer 220 in a manner well known to those of skill in the CMP art. Each load cup 202-206 is coupled to a load cup arm 224, 226, 228 that is configured to pivot between an off-load position (as illustrated) to a load position that is located beneath a corresponding carrier head 208-212. Although three carrier heads are illustrated, CMP apparatus 200 can be configured with any number of carrier heads and with a proportionate number of load cups and associated elements.

In this embodiment, when the CMP apparatus 200 is in operation, robot 214 and removes a wafer 220 from the cache 222 and transports it to one of the load cups 202-206. The wafer 220 is then positioned beneath the corresponding carrier head 208-212. Once the wafer 220 is positioned beneath the appropriate corresponding carrier head 208-212, the carrier head 208-212 is lowered to remove the wafer from the robot 214. The carrier head 208-212 then urges the wafer 220 against the polishing pad, which may move relative to the wafer, thereby polishing the wafer. In an alternative embodiment, the carrier head 208-212 or both the carrier head 208-212 and polishing pad may be caused to move to polish the wafer. Alternatively, the polishing pad may be raised to the carrier head 208-212 and urged against the wafer. In accordance with one exemplary embodiment of the load cup mechanism, each load cup 202-206 is also provided with a plurality of fluid spray nozzles 250 from which the CMP wetting composition of the present invention can be sprayed onto the surface of the wafer before and/or after processing.

The CMP wetting composition of the present invention is preferably used during the processing of wafers, and specifically during the CMP processing of semiconductor wafers to maintain the surface of the wafer in a hydrophilic state because in that state the wafer is less susceptible to contamination. A semiconductor wafer that has just undergone CMP processing is generally hydrophilic, but rapidly becomes hydrophobic upon exposure to air. Accordingly, it is desirable to spray the CMP wetting composition of the present invention onto the wafer surface before that surface becomes hydrophobic.

The CMP wetting composition of the present invention comprises a non-ionic surfactant. The composition also comprises a complexing agent. The composition may also comprise a corrosion inhibiting agent and/or a reducing agent. The composition may also comprise a pH adjuster.

In one exemplary embodiment of the invention, the surfactant has a Draves wetting value in the range of 1-200 seconds. Draves wetting value is defined as the time required for a piece of waxed cotton yarn to sink to the bottom of a 1% concentration solution at 25° C. In a preferred embodiment of the invention, the surfactant of the composition has a Draves wetting value in the range of 1-100 seconds. In another embodiment of the invention, the surfactant has a low hydrophilic/lipophilic balance (HLB), thus being relatively soluble in oil. Preferably, the HLB value of the surfactant is between about 1-15 and more preferably between about 7-10. In yet another embodiment, the surfactant has a contact angle of between about 0 degrees and 40 degrees when the surfactant is contacted with the dielectric surface of the wafer, most preferably, between about 10 degrees and 30 degrees. In yet another embodiment, the surfactant has low foam height, preferably between about 1-100 mm and most preferably between about 25-30 mm.

Suitable surfactants in accordance with the various embodiments of the present invention may comprise any polymer that is soluble in water and has a molecular weight in the range of from 1000 to 1,000,000 and most preferably between 2000-3000. In a preferred embodiment of the invention, the surfactants comprise block copolymers of ethylene oxide and propylene oxide. Examples of block copolymers of ethylene oxide and propylene oxide that may be used in the compositions of the present invention include Pluronic® or Tetronic® surfactants manufactured by BASF Corporation of Mount Olive, N.J. In a preferred embodiment of the invention, the surfactants of the present invention comprise one or more of the surfactants Pluronic® L62LF, L62, L62D, L72, P103, or P123. The surfactant used for the composition typically comprises 0.005-10% by weight.

As previously mentioned, one embodiment of the CMP wetting composition of the present invention further comprises a complexing agent. The complexing agent is preferably capable of forming a soluble complex with trace metal impurities from the CMP process and that may be left on the wafer after the CMP process is complete. For example, in the case that the wafer has been subjected to a damascene process, the complexing agent is preferably capable of forming complexes with residual metal ions that may be present on the wafer after the CMP process. For instance, in a Cu damascene process, the complexing agent is preferably capable of forming complexes with Cu ions. Examples of such suitable complexing agents include but are not limited to organic amines and organic acids having standard reduction potential values of between about 0.1-0.6 volts for a Cu complexation reaction, such as, for instance ethylenediaminetetraacetic acid (EDTA), triethylenetetraamine (TETA), diethylenetriamine (DETA), or nitrilotricetic acid (NTA).

In yet another exemplary embodiment of the CMP wetting composition of the present invention, the wetting composition may optionally further comprise a corrosion inhibitor and/or a reducing agent. Examples of corrosion inhibitors can include, but are not limited to benzotriazole (BTA), 1,2,4-triazole, imidazole, and derivatives thereof, gallic acid, cathechol, or resorcinol. Examples of reducing agents can include, but are not limited to ascorbic acid, glycolic acid, glyoxal, sugars, alcohols, polyhydroxy acids, or polyhydroxy aldehydes.

In another embodiment, the wetting composition may comprise a pH adjuster. The pH adjuster has an ionic strength sufficient to maintain opposite charges between the slurry and the wafer surface. Suitable pH adjusters can include, but are not limited to, organic or inorganic acids having an ionic strength in the range of 10⁻²-10⁻⁵ mol/dm³.

It may be desirable to keep the surface of the wafer wetted with the wetting composition of the present invention in order to maintain the resulting particles that may have adhered to the wafer after exposure to the CMP slurry in clumps. As known in the art, after a wafer has been polished with a slurry, the particles from the CMP slurry may have a tendency to adhere to the wafer. Thus, the wafer is typically subjected to a cleaning process, such as can be used with cleaning system 104 of FIG. 1. It has been found that the adhered particles, because of their lack of sufficient repulsive force, tend to congregate with one another to form particle clumps on the surface of the wafer just after the polishing process.

In previously known CMP processes, deionized water was used to wet the wafer after exposure to the CMP slurry. However, the addition of the deionized water was found to increase the surface potential of each particle in the particle clumps and therefore, increase the electrical repulsion between the particles causing them to deflocculate and disperse across the wafer. As a result, a larger number of particles were found to adhere to the wafer surface, thereby resulting in an increased number of particles that needed to be cleaned off of the wafer. Usage of another embodiment of the CMP wetting composition of the present invention in place of deionized water has been found to counteract this effect and substantially decrease the number of particle clumps present on a wafer. This embodiment of the CMP wetting composition of the present invention is an aqueous solution having substantially the same pH and ionic strength as the slurry used during the CMP polishing process.

Without intending to be bound by theory, it is believed advantageous to maintain substantially the same charge environment on the wafer surface as the environment in which the wafer had been after exposure to CMP slurry. Maintaining the same charge environment causes each particle to each continue to have like charges, continue to be attracted to one another, and thus continue to be in particle clumps.

The CMP wetting composition of the present invention preferably comprises a corrosion inhibitor and a pH adjuster. The concentration and amount of each is dependent on the charge environment in which the wafer was kept. The CMP wetting composition of the present invention preferably has a pH of within ±2 pH unit of the slurry pH and most preferably within ±1 pH units. The ionic strength of the CMP wetting composition of the present invention is preferably between about 10⁻² and 10⁻⁵ mol/dm³. The composition has an ionic strength that is between about ±10⁻² mol/dm³ of an ionic strength of the slurry. Optionally, the CMP wetting composition further comprises an ionic strength adjuster or a surfactant.

In the case that the slurry is an acid, the pH adjuster of the CMP wetting composition of the present invention can comprise an organic or inorganic acid. Examples of suitable organic acids include but are not limited to monocarboxylic acids, such as, for example, ethanoic acid, propanoic acid, or butanoic acid, or dicarboxylic acids, such as, for example, malonic acid, oxalic acid, succinic acid, glutamic acid, or adipic acid, or tricarboxylic acids or hydroxycarboxylic acids, such as, for example, citric acid or tartaric acid. Mixtures of these acids can also be used. Inorganic acids, including, but not limited to, nitric acid, or phosphoric acid, may also be used, however, in such solutions, a relatively larger concentration of the corrosion inhibitor is preferably added to counteract the possibility of corrosion of the metals that may be present on the wafer.

In the case that the slurry has a basic pH, the CMP wetting composition can comprise a base. Examples of suitable bases include, but are not limited to, sodium hydroxide, potassium hydroxide, ammonium hydroxide, and tetraalkylammonium hydroxide. Mixtures of these bases can also be used.

Appropriate corrosion inhibitors may include, but are not limited to, benzotriazole (“BTA”) or any other suitable corrosion inhibitors, such as organic inhibitors having aromatic, aliphatic, or heterocyclic structures thereon. Example of suitable corrosion inhibitors include, but are not limited to, pyrogallol, catechol, resorcinol, gallic acid, 1,2,4-triazole, imidazole and derivatives thereof, and quinaldic acid.

In another embodiment of the CMP wetting composition of the present invention, the composition can further comprise an ionic strength adjuster. Example of suitable ionic strength adjusters include, but are not limited to, organic acids, organic acid salts, inorganic acids, and inorganic acid salts. As will be appreciated by those with skill in the art, an ionic strength adjuster is omitted if the ionic strength of the CMP wetting composition already has a desired ionic strength. In yet another embodiment of the CMP wetting composition of the present invention, a surfactant, such as an anionic or a non-ionic surfactant, can be added to stabilize the particles that are adhered on the wafer. Preferably, a surfactant is added when the wafer includes a metal, inorganic, or organic dielectric layer thereon. Surfactants that may be suitable, include but are not limited to non-ionic surfactants, such as, polyethylene oxide, polypropylene oxide, or block-copolymers of polyethylene oxide and polypropylene oxide, anionic surfactants, such as, sodium or potassium salts of straight chain fatty acids, alkylbenzene sulfonates, alkylnapthalenesulfonates, and cationic surfactants, such as, quartenary ammonium salts, polyoxyethylenated long chain amines, and quatemized polyoxyethylenated long chain amines.

The following example demonstrates the effectiveness of exemplary embodiments of the CMP wetting composition in reducing the number of defects measured on a wafer having a metal, inorganic, or organic dielectric layer thereon, wherein the wafer was previously exposed to at least one slurry during CMP. The example should not be construed as in any way limiting the scope of the present invention.

Each wafer comprised a 200 mm electroplated Cu wafer. Each of the wafers were run through a Momentum CMP apparatus from Novellus Systems, Inc. Each wafer was first subjected to Cu CMP using an abrasive-free C430 slurry and then subjected to a barrier CMP step using a T805 silica abrasive slurry (pH 2.8±.1). An IC 1000 polishing pad available from Rodel, Inc. was used in the CMP apparatus.

After the barrier CMP step, a first group of wafers was subjected to benzotriazole (BTA) dissolved in deionized water. The wafers were then subjected to a purge step using deionized water. Next, the wafers were buffed with an acidic cleaning chemistry, in a first brush unit and cleaned with the same acidic cleaning chemistry in a second brush unit of the Momentum apparatus.

A second group of wafers was subjected to an exemplary embodiment of the CMP wetting composition of the present invention that comprised about 0.1 wt % malonic acid and about 0.1 wt % benzotriazole, wherein the pH was 2.8±0.1 and the ionic strength was about 10⁻² mol/dm³. Specifically, the composition was sprayed from the polishing pads on to the wafer to re-wet the wafer. Each wafer was then unloaded from the polishing station, placed in the spray garage, and wetted with the same composition. The wafers were then subsequently cleaned with an acidic cleaning chemistry. Lastly, the wafers were rinsed with deionized water, then subjected to a spin, rinse, dry unit.

As shown in the graph in FIG. 3, the SP1 count of particles having a particle size of >0.24 microns was about 1200 for the first group. The SP1 count for the second group was about 600, about half the count for the first group. These results demonstrate that use of the CMP wetting composition of the present invention reduces the particles present on wafers, as compared with use of deionized water. Accordingly, a post-CMP buff step to remove particles from the wafer may no longer be required to achieve improved wafer quality.

Thus, there has been provided a method and composition for post-CMP cleaning of metal, inorganic, or organic dielectric thin films that helps to improve the quality of resulting semiconductor wafers.

In the foregoing specification, the invention has been described with reference to specific embodiments. However, it may be appreciated that various modifications and changes can be made without departing from the scope of the invention as set forth in the appended claims. Accordingly, the specification and figures are to be regarded as illustrative rather than as restrictive, and all such modifications are intended to be included within the scope of the present invention.

1. A composition for wetting a surface of a material having a dielectric layer during a chemical mechanical process (CMP) after the material has been exposed to a slurry, the composition comprising:
a non-ionic surfactant having an HLB value in the range from 1 to 15, in an amount of between about 0.005-10% weight of the composition.

2. The composition of claim 1, wherein the surfactant when dissolved in a liquid has a contact angle when the fluid contacts the surface of the material having a dielectric layer and wherein the contact angle is in the range of 0 to 40 degrees.

3. The composition of claim 2, wherein the contact angle is in the range of 10 to 30 degrees.

4. The composition of claim 1, wherein the HLB value is in the range from 7-10.

5. The composition of claim 1, wherein the surfactant comprises a polymer comprising at least one selected from the group ethylene oxide, propylene oxide, or a block copolymer of ethylene oxide and propylene oxide.

6. The composition of claim 1, wherein the surfactant comprises at least one selected from the group comprising Pluronic® or Tetronic®.

7. The composition of claim 1, further comprising a complexing agent capable of complexing with trace metal impurities and Cu residue left by the slurry.

8. The composition of claim 7, wherein the complexing agent is selected from the group comprising organic amines and organic acids.

9. The composition of claim 8, wherein the complexing agent has standard reduction potential values of between about 0.1-0.6 volts for a Cu complexation reaction.

10. The composition of claim 9, wherein the complexing agent is selected from the group comprising ethylenediaminetetraacetic acid (EDTA), triethylenetetraamine (TETA), diethylenetriamine (DETA), and nitrilotricetic acid (NTA).

11. The composition of claim 7, further comprising:
a reducing agent.

12. The composition of claim 11, wherein the reducing agent is selected from the group comprising ascorbic acid, glycolic acid, glyoxal, sugars, alcohols, polyhydroxy acids, and polyhydroxy aldehydes.

13. The composition of claim 9, further comprising a corrosion inhibitor.

14. The composition of claim 13, wherein the corrosion inhibitor is selected from the group comprising benzotriazole (BTA), 1,2,4-triazole, imidazole, and derivatives thereof, gallic acid, catechol, and resorcinol.

15. The composition of claim 11, further comprising a pH adjuster.

16. The composition of claim 15, wherein the pH adjuster is selected from the group comprising an organic or inorganic acid having an ionic strength in the range of 10⁻²-10⁻⁵ mol/dm³.

17. The composition of claim 13, wherein the composition has an ionic strength that is between about ±10⁻² mol/dm³ of an ionic strength of the slurry.

18. A composition for wetting a surface of a material having a dielectric constant during a chemical mechanical process (CMP) after the material has been exposed to a slurry, the composition comprising:
a non-ionic surfactant in an amount of between about 0.005-10% weight of the composition, wherein the surfactant has an HLB value in the range from 1 to 15;
a complexing agent capable of complexing with trace metal impurities and Cu residue left by the slurry;
a corrosion inhibitor; and
a pH adjuster.

19. The composition of claim 18, wherein the composition has an ionic strength that is between about ±10⁻² mol/dm³ of an ionic strength of the slurry.

20. A composition for wetting particles on a wafer after a chemical-mechanical polishing process, wherein the wafer has been exposed to a slurry having a pH, the solution comprising:
a corrosion inhibiting agent; and
a pH adjuster,
wherein the composition has a pH that is ±1 pH unit of the pH of the slurry and an ionic strength of between about 10⁻² and 10⁻⁵ mol/dm³.

21. The composition of claim 20, wherein the pH adjuster is an acid.

22. The composition of claim 21, wherein the acid is an organic acid.

23. The composition of claim 22, wherein the organic acid is selected from the group comprising: a monocarboxylic acid, dicarboxylic acid, tricarboxylic acid.

24. The composition of claim 23, wherein the monocarboxylic acid is selected from the group comprising ethanoic acid, propanoic acid, and butanoic acid.

25. The composition of claim 23, wherein the dicarboxylic acid is selected from the group comprising malonic acid, oxalic acid, succinic acid, glutamic acid, and adipic acid.

26. The composition of claim 23, wherein the tricarboxylic acid is citric acid.

27. The composition of claim 20, wherein the pH adjuster is a base.

28. The composition of claim 27, wherein the base is selected from the group comprising sodium hydroxide, potassium hydroxide, or ammonium hydroxide, and tetraalkylammounium hydroxide, and mixtures thereof.

29. The composition of claim 20, wherein the corrosion inhibiting agent has an aromatic structure.

30. The composition of claim 20, wherein the corrosion inhibiting agent has an aliphatic structure.

31. The composition of claim 20, wherein the corrosion inhibiting agent has a heterocyclic structure.

32. The composition of claim 20, wherein the corrosion inhibitor is selected from the group comprising benzotriazole, pyrogallol, catechol, resorcinol, gallic acid, 1,2,4-triazole, imidazole and derivatives thereof, and quinaldic acid.

33. The composition of claim 20, further comprising a surfactant.

34. The composition of claim 33, wherein the surfactant is selected from the group comprising non-ionic surfactants, such as, polyethylene oxide, polypropylene oxide, or block-copolymers of polyethylene oxide and polypropylene oxide, anionic surfactants, such as, sodium or potassium salts of straight chain fatty acids, alkylbenzene sulfonates, alkylnapthalenesulfonates, and cationic surfactants, such as, quartenary ammonium salts, polyoxyethylenated long chain amines, and quaternized polyoxyethylenated long chain amines.

35. The composition of claim 34, wherein the organic acid is malonic acid in the amount of about 0.1 wt % and the corrosion inhibiting agent is benzotriazole in the amount of about 0.1 wt %.

36. A method of processing a wafer, the method comprising:
polishing the wafer with a slurry having a pH and an ionic strength;
after the wafer has been polished, applying a post-CMP wetting composition to the wafer, wherein the post-CMP wetting composition comprises:
a non-ionic surfactant having an HLB value in the range from 1 to 15, in an amount of between about 0.005-10% weight of the composition;
a complexing agent capable of complexing with trace metal impurities and Cu residue left by the slurry;
a corrosion inhibitor; and
a pH adjuster.

37. The method of claim 36, wherein the step of applying further comprises spraying the compositing on the wafer.

38. The method of claim 37, wherein the step of spraying further comprises loading the wafer into a load cup.

39. The method of claim 36, wherein the step of applying further comprises brushing the composition on the wafer.

40. A method of processing a wafer, the method comprising:
polishing the wafer with a slurry having a pH and an ionic strength;
after the wafer has been polished, applying a CMP wetting composition to the wafer, wherein the CMP wetting composition comprises:
a corrosion inhibiting agent; and
a pH adjuster,
wherein the composition has a pH that is ±1 pH unit of the pH of the slurry and an ionic strength of between about 10⁻² and 10⁻⁵ mol/dm³.

41. The method of claim 40, wherein the step of applying further comprises spraying the composition on the wafer.

42. The method of claim 41, wherein the step of spraying further comprises loading the wafer into a load cup.

43. The method of claim 42, wherein the step of applying further comprises brushing the composition on the wafer.
